(19) United States
(12) Patent Application Publication
(10) Pub. No.: US 2009/0021176 A1
(43) Pub. Date: Jan. 22, 2009

(54) SEMICONDUCTOR DEVICE

(75) Inventor: Yoshinori IMANAKA, Kyoto (JP)

Correspondence Address: CANTOR COLBURN, LLP, 20 Church Street, 22nd Floor, Hartford, CT, 06103, US

(73) Assignee: ROHM CO., LTD., Kyoto (JP)

(21) Appl. No.: 12/168,802

(22) Filed: Jul. 7, 2008

(30) Foreign Application Priority Data
Jul. 6, 2007 (JP) JP2007-178710

(51) Int. Cl. H05B 41/00; H03K 17/28

(52) U.S. Cl. 315/209 T; 327/392

(57) ABSTRACT

A control terminal is connected to an external resistor, and is connected to a time constant capacitor. A control unit compares a control voltage with a threshold voltage, and switches the function of a semiconductor device according to the comparison results. A charge/discharge circuit charges or discharges the time constant capacitor connected to the control terminal. The semiconductor device uses the voltage at the control terminal, which changes according to the charging operation or the discharging operation performed by the charge/discharge circuit, as a time constant voltage.

### BACKGROUND OF THE INVENTION

1. Field of the Invention

The present invention relates to a technique for generating a time constant voltage by charging or discharging a capacitor.

2. Description of the Related Art

Many semiconductor devices employ a time constant circuit for timing a predetermined period of time. The time constant circuit generates a time constant voltage by charging or discharging a capacitor. Related techniques are described in Patent documents 1 and 2. Such an arrangement allows the passage of a predetermined period of time to be detected by making a comparison between the time constant voltage and a threshold voltage.

In a case in which the time constant is to be increased, there is a need to employ a capacitor with a large capacitance. Such a capacitor must be provided in the form of an external chip component to a semiconductor integrated circuit. Also, in some cases, in order to change the time constant, such a capacitor in the form of a chip component is employed.

### [Patent Document 1]

Japanese Patent Application Laid Open No. 2004-147048

### [Patent Document 2]

Japanese Patent Application Laid Open No. H8-172384

However, in a case in which an external capacitor is provided to the time constant circuit, there is a need to provide terminals (pins) which allow the capacitor to be connected to the semiconductor integrated circuit. Such an increase in the number of terminals provided to the semiconductor integrated circuit increases the space occupied by the circuit, leading to increased costs.

### SUMMARY OF THE INVENTION

The present invention has been made in view of such problems. Accordingly, it is a general purpose of the present invention to provide a semiconductor device which is capable of generating a time constant voltage while suppressing enlargement of the circuit area.

An embodiment of the present invention relates to a semiconductor device. The semiconductor device comprises: a control terminal which is connected to one terminal of an external resistor, the other terminal of which is connected to a fixed voltage terminal, and which is connected to a time constant capacitor; a control unit which compares the voltage at the control terminal with a predetermined threshold voltage, and which switches the function of the semiconductor device according to the comparison results; and a charge/discharge circuit which charges or discharges the time constant capacitor connected to the control terminal. The voltage at the control terminal, which changes according to the charging operation or discharging operation performed by the charge/discharge circuit, is used as a time constant voltage.

Some semiconductor devices have a terminal via which either a high level or a low level voltage is fixedly input, which is used for switching the function of the semiconductor device. With the present embodiment, such a terminal is provided as a common terminal which is also connected to a capacitor for generating a time constant voltage, thereby providing a reduced circuit area. The phrase “switches the function of the semiconductor device” means that the function provided by the semiconductor device is changed, or the operation of the semiconductor device is changed.

The control unit may include: a determination comparator which compares the voltage at the control terminal with the threshold voltage; and a latch circuit which latches the output of the determination comparator at a timing at which a trigger signal is generated when the semiconductor device is started up. The function of the semiconductor device may be switched according to the output of the latch circuit.

With such an arrangement, the voltage at the control terminal is identified at a timing at which a trigger signal is generated. Accordingly, after this timing, there is no need to maintain the voltage at the control terminal at a fixed value. Thus, after this timing, the time constant capacitor can be charged or discharged as desired.

The charge/discharge circuit may include: a first time constant circuit which draws a sink current from the control terminal, and which compares the voltage at the control terminal with a first threshold voltage; and a second time constant circuit which supplies a source current to the control terminal, and which compares the voltage at the control terminal with a second threshold voltage. The semiconductor device may select one of the first time constant circuit or the second time constant circuit according to the comparison results made by the control unit.

Such an arrangement includes a circuit which is capable of generating a sink current and a source current. Thus, such an arrangement allows the voltage at the time constant capacitor to be switched as desired between the positive direction and the negative direction.

The first time constant circuit may include a first current source which draws a current from the control terminal, and a first comparator which compares the voltage at the control terminal with the first threshold voltage. The second time constant circuit may include a second current source which supplies a current to the control terminal, and a second comparator which compares the voltage at the control terminal with the second threshold voltage. The semiconductor device may selectively set either the first current source or the second current source to the active state according to the determination results made by the control unit.

A semiconductor device according to another embodiment may further include a voltage source which generates a predetermined voltage; and a voltage output terminal via which the voltage thus generated is output externally. The other terminal of the external resistor may be connected to one of the voltage output terminal or the ground terminal.

The external resistor may be connected between the control terminal and the voltage output terminal. Also, the external resistor may be connected between the control terminal and the ground terminal. The time constant capacitor may be connected in parallel with the external resistor. The time constant capacitor may be connected between the control terminal and the ground terminal.

The time constant capacitor may be connected between the control terminal and the capacitor terminal.

The semiconductor device may be a driving circuit for a fluorescent lamp, and may further include a malfunction detection unit which detects whether or not a circuit malfunction continuously occurs during a predetermined malfunction detection period. The voltage at the control terminal, which changes according to the charging operation or the discharging operation performed by the charge/discharge circuit, may be used for timing the malfunction detection period.

The semiconductor device may be a driving circuit for a fluorescent light. The semiconductor device may include a dimmer terminal via which an analog voltage is input from an external source for performing the dimming operation of the fluorescent lamp, and a dimmer circuit which generates a pulse signal by slicing a cyclic voltage using the analog voltage input via the dimmer terminal, and which performs a burst dimming operation of the fluorescent light using the pulse signal thus generated. The dimmer circuit may switch the polarity of the burst dimming operation according to the determination results made by the control unit.

The semiconductor device may be a driving circuit for a fluorescent lamp, and may include a dimmer terminal via which a pulse signal is input from an external source for performing a burst dimmer operation for the fluorescent lamp, and a dimmer circuit which performs the burst dimmer operation for the fluorescent lamp using the pulse signal. The dimmer circuit may switch the polarity of the burst dimmer operation according to the determination results made by the control unit.

The semiconductor device may be a driving circuit for a fluorescent light. The semiconductor device may be used as a master circuit or a slave circuit of a circuit pair which comprises two driving circuits, one of which provides a function as a master circuit, and the other of which provides a function as a slave circuit. With such an arrangement, either the master circuit or the slave circuit may be switched according to the determination results made by the control unit.

The semiconductor device may be a driving circuit for driving a fluorescent light, and may switch the striking frequency for the external electrode fluorescent lamp, according to the determination results made by the control unit.

It is to be noted that any arbitrary combination or rearrangement of the above-described structural components and so forth is effective as and encompassed by the present embodiments.

Moreover, this summary of the invention does not necessarily describe all necessary features so that the invention may also be a sub-combination of these described features.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a circuit diagram which shows a configuration of a semiconductor device according to the present embodiment;

FIGS. 2A through 2D are circuit diagrams which show variations of an external circuit;

FIG. 3 is a time chart which shows the operation of the semiconductor device shown in FIG. 1; and

FIG. 4 is a block diagram which shows a driving circuit for a fluorescent lamp, utilizing the semiconductor device shown in FIG. 1.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

In the present specification, the state represented by the phrase “the member A and the member B are connected” includes a state in which the member A and the member B are physically and directly connected to each other. Also, the state represented by such a phrase include a state in which the member A and the member B are indirectly connected to each other via another member that does not affect the electric connection between the member A and the member B.

Similarly, the state represented by the phrase “the member C is provided between the member A and the member B” includes a state in which the member A and the member C, or the member B and the member C are physically and directly connected to each other. Also, the state represented by such a phrase include a state in which the member A and the member C, or the member B and the member C are indirectly connected to each other via another member that does not affect the electric connection.

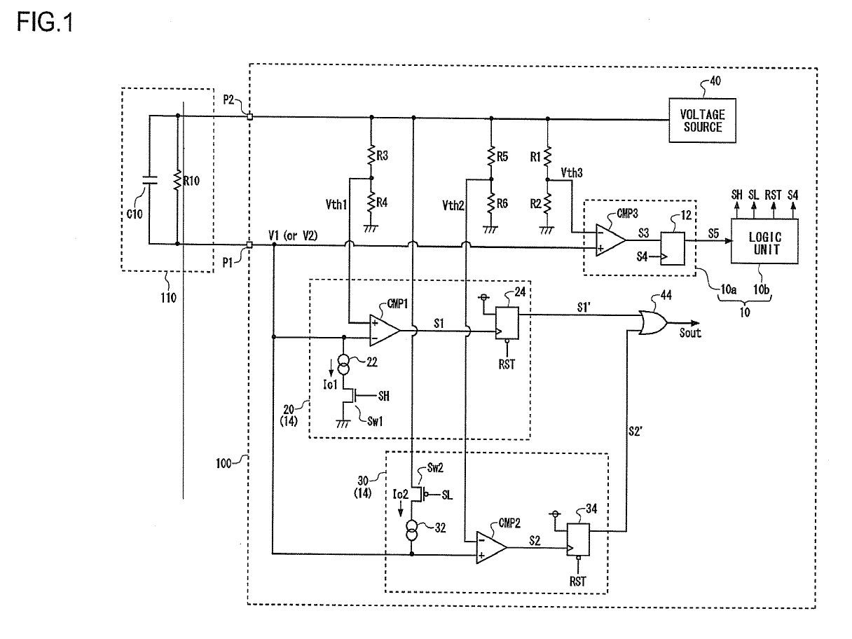

FIG. 1 is a circuit diagram which shows a configuration of a semiconductor device 100 according to the present embodiment. The semiconductor device 100 is capable of switching the function or the operation of the circuit according to the level of a control voltage V1 input from an external source. That is to say, when the control voltage V1 is at the high level, the semiconductor device 100 performs a first function or a first operation, and when the control voltage V1 is at the low level, the semiconductor device 100 performs a second function or a second operation. Furthermore, the semiconductor device 100 has a function of generating a time constant voltage V2 having a level that changes over time. The present invention can be widely applied to such a circuit without restricting its utility.

The semiconductor device 100 includes a control terminal P1 which allows the control voltage V1 to be received from an external source. An external resistor R10 is connected to the control terminal P1 in the form of an external component. When the control terminal P1 is pulled down via the external resistor R10, the control voltage V1 is set to the low level (VL), and when the control terminal P1 is pulled up to a predetermined voltage level, the control voltage V1 is set to the high level VH. FIG. 1 shows the state in which the control voltage V1 is set to the high level state.

That is to say, the semiconductor device 100 and the external resistor R10 are mounted on a common printed circuit board. Furthermore, the semiconductor device 100 is designed on the assumption that voltage at the high level or the low level is supplied to the semiconductor device 100 via the external resistor R10.

Furthermore, a time constant capacitor C10, which allows the time constant voltage V2 to be generated, is provided in the form of an external component to the semiconductor device 100. Also, the time constant capacitor C10 is mounted on the same printed circuit board as the external resistor R10. The semiconductor device 100 generates the time constant voltage V2 by charging or discharging the time constant capacitor C10. The combination of the external resistor R10 and the time constant capacitor C10 will be referred to as the “external circuit 110”.

The semiconductor device 100 according to the present embodiment has a feature whereby, instead of providing a dedicated terminal that allows the time constant capacitor C10 to be connected, the time constant capacitor C10 is connected via the control terminal P1 as a common terminal. That is to say, one terminal of the time constant capacitor C10 is connected to the time constant capacitor C10 via which the control voltage V1 is to be applied.

In other words, one terminal of the external resistor R10, the other terminal of which is connected to a fixed voltage terminal, is connected to the control terminal P1. Furthermore, the time constant capacitor C10 is connected to the control terminal P1. With such an arrangement, at a point in time, the voltage of the control terminal P1 is set to the control voltage V1, and at another point in time, the voltage of the control terminal P1 is set to the time constant voltage V2.

The semiconductor device 100 includes a control unit 10, a charge/discharge circuit 14, and a voltage source 40.

The voltage source 40 generates a stable voltage necessary for the internal components or the external components of the semiconductor device 100. Such a voltage will be referred to as a “stabilized voltage VREG” hereafter. A voltage output terminal P2 is a terminal which allows the stabilized voltage VREG to be output externally, and via which a capacitor (not shown) VREG is connected for smoothing the stabilized voltage.

The semiconductor device 100 shown in FIG. 1 uses the stabilized voltage VREG in order to pull up the control voltage V1 at the control terminal P1 via the external resistor R10. That is to say, in a case in which the control voltage V1 is to be set to the high level state, the external resistor R10 is connected between the control terminal P1 and the voltage output terminal P2. On the other hand, in a case in which the control voltage V1 is to be set to the low level state, the external resistor R10 is connected between the control terminal P1 and the ground terminal. It should be noted that, in a case in which the control voltage V1 is to be set to the high level state, one terminal of the external resistor R10 may be connected to a battery voltage or a line to which an external source voltage is applied, instead of the terminal of the external resistor R10 being connected to the voltage output terminal P2.

The control unit 10 compares the control voltage V1 at the control terminal P1 with a predetermined threshold voltage Vth3, and switches the function or the operation of the semiconductor device 100 based upon the comparison results.

The charge/discharge circuit 14 charges or discharges the time constant capacitor C10 connected to the control terminal P1. The “capacitor charging operation” is an operation for changing the charges at the electrodes of the capacitor such that the electric potential difference is increased between both terminals. Furthermore, the “capacitor discharging operation” is an operation for changing the charges at the electrodes of the capacitor such that the electric potential difference is reduced between both terminals. The charge/discharge circuit 14 should have a configuration which provides at least either of a function for charging the capacitor C10 or a function for discharging the capacitor C10.

The semiconductor device 100 uses the voltage at the control terminal P1, which changes according to the charging operation or the discharging operation of the charge/discharge circuit 14, as the time constant voltage V2. That is to say, the external control voltage V1 is supplied in a fixed manner. Accordingly, after the setting of the function or the operation of the semiconductor device 100 by determining the level of the control voltage V1, there is no need to supply the control voltage V1. With such an arrangement, after the determination of the level of the control voltage V1, or during a period in which there is no need to supply the control voltage V1, the semiconductor device 100 shown in FIG. 1 generates the time constant voltage V2 by charging or discharging the time constant capacitor C10.

The semiconductor device 100 shown in FIG. 1 has a common terminal that serves as a control terminal which allows the control voltage V1 to be input, and that also serves as a capacitor connection terminal via which a capacitor is connected for generating the time constant, thereby reducing the number of terminals.

Description will be made below regarding a specific example of the configuration of the semiconductor device 100.

The control unit 10 includes a determination unit 10a and a logic unit 10b. The determination unit 10a includes a determination comparator CMP3 and a determination latch circuit 12. The determination comparator CMP3 compares the voltage V1 at the control terminal P1 with the threshold voltage Vth3. The determination comparator CMP3 outputs a determination signal S3, which is switched between the high level state and the low level state according to the comparison result. The threshold voltage Vth3 is generated by dividing the stabilized voltage VREG by means of the first resistor R1 and the second resistor R2.

The determination latch circuit 12 latches the determination signal S3, which is output from the determination comparator CMP3, using a trigger signal S4 that is switched to the high level state at a predetermined timing. Various kinds of logic circuits may be used for the latch circuit, examples of which include a D latch, a D flip-flop, etc. The trigger signal S4 is preferably generated at a timing at which the control voltage V1 can be stably supplied, immediately after the semiconductor device 100 is started up. The logic unit 10b switches the trigger signal S4 to the high level state at a predetermined timing, and supplies the trigger signal S4 to the determination latch circuit 12.

During the period until the determination latch circuit 12 is reset according to a reset signal, the determination latch circuit 12 continues to hold the determination signal S3 received from the determination comparator CMP3. The determination signal S5 held by the determination latch circuit 12 is input to the logic unit 10b. The logic unit 10b sets the function and the operation of the semiconductor device 100 according to the level of the determination signal S5.

The charge/discharge circuit 14 includes a first time constant circuit 20 and a second time constant circuit 30.

The first time constant circuit 20 draws a sink current Ic1 via the control terminal P1, and generates a time constant voltage V2 at the control terminal P1. The first time constant circuit 20 compares the time constant voltage V2 with a first threshold voltage Vth1, thereby timing a predetermined period of time (which will be referred to as the “first time constant” hereafter) T1. The first threshold voltage Vth1 is generated by dividing the stabilized voltage VREG by means of a third resistor R3 and a fourth resistor R4. The second time constant circuit 30 supplies (pushes) a source current Ic2 to the control terminal P1, and generates the time constant voltage V2 at the control terminal P1. The second time constant circuit 30 compares the time constant voltage V2 with a second threshold voltage Vth2, thereby timing a predetermined period of time (which will be referred to as the “second time constant” hereafter) c2. The second threshold voltage Vth2 is generated by dividing the stabilized voltage VREG by means of a fifth resistor R5 and a sixth resistor R6. Let us say that the time constant τ1 of the first time constant circuit 20 is equal to the time constant τ2 of the second time constant circuit 30. Accordingly, these time constants will be simply referred to as “time constant τ” hereafter.

The logic unit 10b selects either of the first time constant circuit 20 or the second time constant circuit 30 based upon the comparison result made by the determination unit 10b, i.e., according to the determination signal S5, so as to time the period of time of the time constant τ. That is to say, the logic unit 10b switches the time constant circuit to be selected, between the time constant circuit 20 and the second time constant circuit 30, according to the circuit state of an external circuit 110.

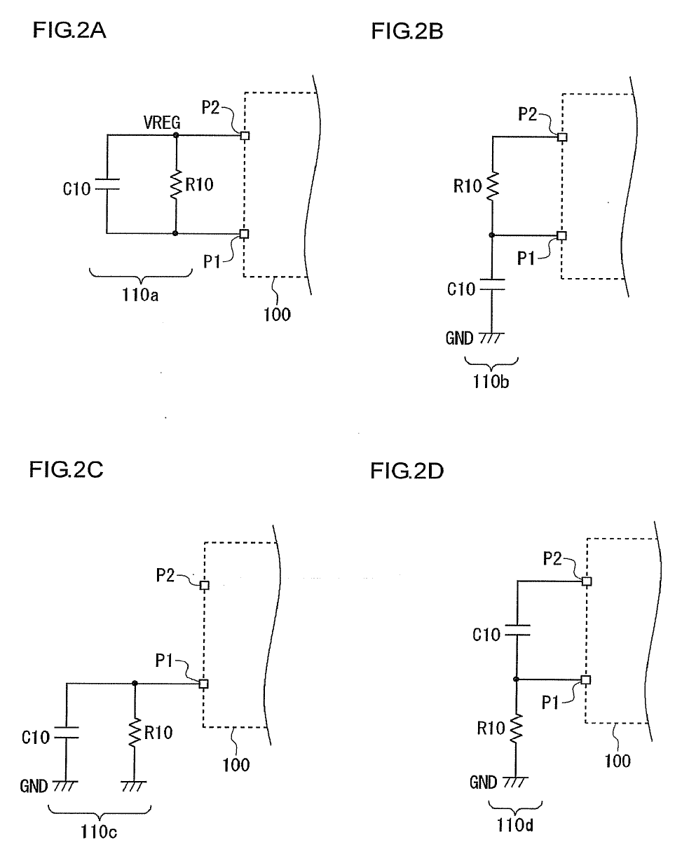

FIG. 2A through FIG. 2D are circuit diagrams which show variations of the external circuit 110. In the external circuits 110a and 110b shown in FIG. 2A and FIG. 2B, the external resistor R10 is provided between the control terminal P1 and the voltage output terminal P2, which pulls up the control voltage V1 to the high level state. On the other hand, in the external circuits 110c and 110d shown in FIG. 2C and FIG. 2D, the external resistor R10 is provided between the control terminal P1 and the ground terminal GND, which pulls down the control voltage V1 to the low level state.

It should be noted that any one of the following combinations of the external circuits 110 may be selected.

(1) A combination of the external circuit 110a and the external circuit 110c.
(2) A combination of the external circuit 110a and the external circuit 110d.
(3) A combination of the external circuit 110b and the external circuit 110c.
(4) A combination of the external circuit 110b and the external circuit 110d.

In a case in which the combination (1) is selected, the time constant capacitor C10 is provided in parallel with the external resistor R10. In a case in which the combination (2) is selected, the time constant capacitor C10 is provided between the control terminal P1 and the voltage output terminal P2. In a case in which the combination (3) is selected, the time constant capacitor C10 is provided between the control terminal P1 and the ground terminal GND. In a case in which the combination (4) is selected, the time constant capacitor C10 and the external resistor R10 are provided in series between the voltage output terminal P2 and the ground terminal GND.

When the control voltage V1 is pulled up to the high level state, i.e., when the external circuit 110a or the external circuit 110b is selected, the semiconductor device 100 sets the first time constant circuit 20 to the active state.

In this case, in the initial state, the time constant voltage V2 is equal to the control voltage V1 (=VREG). When the first time constant circuit 20 is set to the active state in order to start to time the period of time of the time constant τ, the sink current Ic1 flows into the semiconductor device 100 from the time constant capacitor C10. Accordingly, the electric potential at the control terminal P1 drops according to the elapse of time, thereby generating the time constant voltage V2. The first time constant circuit 20 provides the time constant T1, which is a period of time in which the time constant voltage V2 drops from the VREG to the Vth1.

On the other hand, when the control voltage V1 is pulled down to the low level state, i.e., when the external circuit 110c or the external circuit 110d is selected, the second time constant circuit 30 is set to the active state.

In this case, in the initial state, the time constant voltage V2 is equal to the control voltage V1 (=0 V). When the second time constant circuit 30 is set to the active state in order to start to time the period of time of the time constant τ, the source current Ic2 flows form the semiconductor device 100 to the time constant capacitor C10. Accordingly, the electric potential at the control terminal P1 rises according to the elapse of time, thereby generating the time constant voltage V2. The second time constant circuit 30 provides the time constant T2, which is a period of time in which the time constant voltage V2 rises from 0 V to the Vth1.

In the first circuit shown in FIG. 1, the first time constant circuit 20 includes: a first current source 22 which draws the sink current Ic1 via the control terminal P1; a first comparator CMP1 which compares the voltage V2 at the control terminal P1 with the first threshold voltage Vth1; a first switch SW1 which controls the ON/OFF operation of the first current source 22; and a first latch circuit 24 which latches the output of the first comparator CMP1.

The second time constant circuit 30 includes: a second current source 32 which supplies the source current Ic2 to the control terminal P1; a second comparator CMP2 which compares the voltage V2 at the control terminal P1 with the second threshold voltage Vth2; a second switch SW2 which controls the ON/OFF operation of the second current source 32; and a second latch circuit 34 which latches the output of the second comparator CMP2.

Also, a charge/discharge resistor may be employed, instead of the first current source 22 or the second current source 32. In this case, the time constant τ is determined based upon the capacitance of the time constant capacitor C10 and the resistance of the charge/discharge resistor.

The logic unit 10b selectively sets either the first current source 22 or the second current source 32 to the active state according to the determination signal S5 received from the determination unit 10a. That is to say, in a case in which the control voltage V1 has been set to the high level state, the logic unit 10b instructs the first current source 22 to operate, and in a case in which the control voltage V1 has been set to the low level state, the logic unit 10b instructs the second current source 32 to operate.

At a timing when the period of time τ starts to be timed, the logic unit 10b outputs either a switching control signal SH or SL so as to turn on either the first switch SW1 or the second switch SW2. As a result, the time constant voltage V2 starts to change. After the passage of the time constant τ, transition occurs with respect to the level of either the output signal (which will be referred to as the “comparison signal” hereafter) S1 or S2 output from the first comparator CMP1 or the second comparator CMP2. The comparison signal S1 or S2 is latched by the first latch circuit 24 or the second latch circuit 34. Accordingly, the output of the first latch circuit 24 or the second latch circuit 34 is set to the high level state.

An OR gate 44 outputs the logical OR (which will be referred to as the “output signal Sout” hereafter) of the output signal S1′ output from the first latch circuit 24 and the output signal S2′ output from the second latch circuit 34. After the passage of the time constant τ after the logic unit 10b transmits an instruction to start to perform the timing operation, the output signal Sout is set to the high level state.

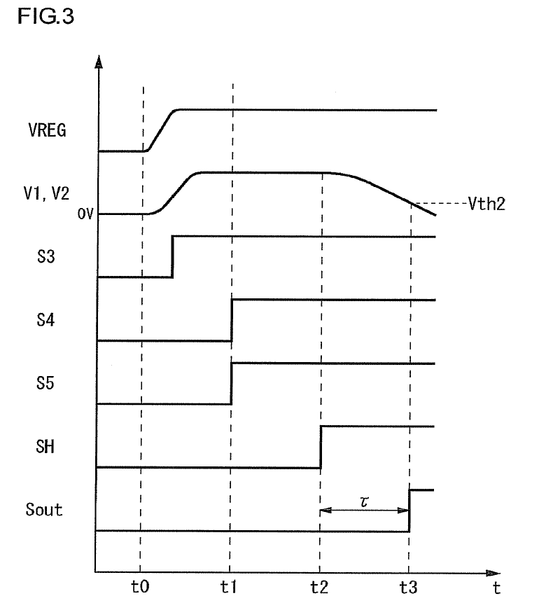

FIG. 3 is a time chart which shows the operation of the semiconductor device 100 shown in FIG. 1. The time chart in FIG. 3 shows a case in which the control voltage V1 is set to the high level state. When the semiconductor device 100 is started up at the point in time t0, the stabilized voltage VREG is generated by the voltage source 40. At the timing t1 after the stabilized voltage VREG has become stable, the trigger signal S4 is set to the high level state so as to identify the level of the control voltage V1.

At the timing t2 when the timing operation is started for the time constant τ, the logic unit 10b sets the switch control signal SH to the high level state. This turns on the first switch SW1, thereby setting the first current source 22 to the active state. As a result, the time constant voltage V2 drops according to time. When the time constant voltage V2 becomes smaller than the second threshold voltage Vth2 at the point in time t3 after the passage of the time constant τ from the point in time t2, the comparison signal S1 is set to the high level state.

In a case in which the period of time of the time constant τ is repeatedly timed, the first latch circuit 24 and the second latch circuit 34 are reset according to a reset signal RST before the next timing operation, and the same operation is repeatedly performed.

As described above, with the semiconductor device 100 shown in FIG. 1, the period of time of the time constant τ can be timed regardless of whether the control voltage V1 is set to the high level state or the low level state. It should be noted that the time constant of the first time constant circuit 20 and the second time constant circuit 30 may be set to values that differ from one another.

Furthermore, as shown in FIG. 2A through FIG. 2D, in a case in which the control voltage V1 is to be set to the high level state, one terminal of the external resistor R10 is connected to the voltage output terminal P2. The voltage source 40 generates the stabilized voltage VREG at a constant value, thereby suppressing irregularities in the time constant τ.

It should be noted that in a case in which such irregularities in the time constant τ are permissible, or in a case in which the semiconductor device 100 does not have the voltage source 40, the one terminal of the external resistor R10 may be connected to the battery voltage or a power line from an external power supply.

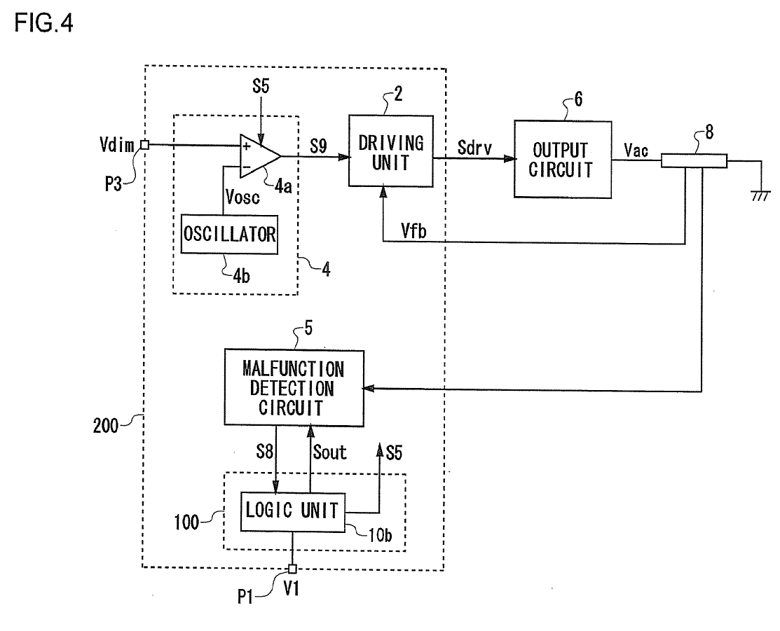

Next, description will be made regarding an example of an application of the semiconductor device 100 shown in FIG. 1. FIG. 4 is a block diagram which shows a driving circuit 200 for a fluorescent lamp utilizing the semiconductor device 100 shown in FIG. 1.

The driving circuit 200 and an output circuit 6 form an inverter. The driving circuit 200 generates a pulse-modulated driving signal Sdrv, and outputs the driving signal drv to the output circuit 6. The output circuit 6 includes a switching circuit such as an H-bridge circuit, half-bridge circuit, or the like, and a transformer. The output circuit 6 controls the switching circuit according to the driving signal Sdrv so as to generate an AC voltage Vac, and supplies the AC voltage Vac thus generated to the fluorescent lamp 8. The inverter has a known configuration, and accordingly, detailed description thereof will be omitted.

The driving circuit 200 includes a driving unit 2, a dimmer circuit 4, a malfunction detection circuit 5, and the semiconductor device 100. The driving unit 2 receives the current that flows through the fluorescent lamp 8 as a feedback signal Vfb, and generates the driving signal Sdrv so as to maintain the feedback signal Vfb at a constant value. The malfunction detection circuit 5 detects malfunctions of the fluorescent lamp 8 such as a short-circuit state, an open-circuit state, a state in which light cannot be emitted, etc. In a case in which such a malfunction has occurred, the malfunction detection circuit 5 outputs a malfunction detection signal S8 to the semiconductor device 100.

When the driving circuit 200 is started up, the semiconductor device 100 identifies the control voltage V1 supplied to the control terminal P1. Furthermore, when a level transition occurs with respect to the malfunction detection signal S8, the semiconductor device 100 starts to time the period of time of the time constant τ. After the passage of the time constant τ, the output signal Sout is output to the malfunction detection circuit 5. In a case in which such a malfunction continuously occurs during a predetermined malfunction detection period of time τ, the malfunction detection circuit 5 executes a predetermined circuit protection operation.

In FIG. 4, an analog voltage Vdim is input to a dimmer terminal P3. The dimmer circuit 4 includes a dimmer comparator 4a and an oscillator 4b. The oscillator 4b generates a cyclic voltage Vosc in the shape of a triangular waveform or a sawtooth waveform. The dimmer comparator 4a slices the cyclic voltage Vosc using the analog voltage Vdim, thereby generating a pulse signal S9. The driving unit 2 performs a burst dimming operation for the fluorescent lamp 8 using the pulse signal S9.

Description will be made regarding an example of the function and the operation of the driving circuit 200, which are switched according to the control voltage V1.

The dimmer circuit 4 switches the polarity of the burst dimming according to the determination signal S5 (i.e., the control voltage V1) which is the determination result made by the determination unit 10a of the semiconductor device 100. That is to say, when the first polarity is selected, the ON cycle of the fluorescent lamp 8 is increased according to an increase in the analog voltage Vdim, and when the second polarity is selected, the ON cycle of the fluorescent lamp 8 is increased according to a reduction in the analog voltage Vdim.

Another modification may be made in which the dimmer comparator 4a and the oscillator 4b are eliminated, and the pulse signal S9, which is to be used for the dimming operation, is directly input from an external source. With such a modification, the driving unit 2 may switch the polarity of the burst dimming according to the control voltage V1. That is to say, when the first polarity is selected, the pulse signal S9 at the high level is assigned to the ON cycle of the fluorescent lamp 8, and when the second polarity is selected, the pulse signal S9 at the low level is assigned to the ON cycle of the fluorescent lamp 8.

According to another modification, two driving circuits 200 perform operations as a pair. With such a modification, one driving circuit 200 provides a function as a master circuit. The other driving circuit provides a function as a slave circuit. In this case, the settings of the master circuit and the slave circuit may be made according to the control voltage V1.

According to yet another modification, the fluorescent lamp 8 is an external electrode fluorescent lamp (EEFL). With such a modification, the striking frequency for the external electrode fluorescent lamp is switched according to the control voltage V1.

The driving circuit 200 shown in FIG. 4 is capable of suitably switching the function and the operation of the circuit. Furthermore, the driving circuit 200 is capable of performing the timing operation necessary for malfunction detection.

The embodiment has been described for exemplary purposes only, and is by no means intended to be interpreted restrictively. Rather, it can be readily conceived by those skilled in this art that various modifications may be made by making various combinations of the aforementioned components or processes, which are also encompassed in the scope of the present invention.

Description has been made in the embodiment regarding an arrangement in which the time constant voltage V2 is used for the timing operation. However, the present invention is not restricted to such an arrangement. Also, the present invention may be applied to other arrangements. For example, the time constant voltage V2 may be used as a soft start voltage for a soft start operation.

Description has been made in the embodiment regarding an arrangement in which the control voltage V1 thus input is switched between binary values, i.e., the high level value and the low level value. Also, an arrangement may be made in which the control voltage V1 is switched among three or more values.

While the preferred embodiments of the present invention have been described using specific terms, such description is for illustrative purposes only, and it is to be understood that changes and variations may be made without departing from the spirit or scope of the appended claims.

What is claimed is:

1. A semiconductor device comprising:
a control terminal which is connected to one terminal of an external resistor, the other terminal of which is connected to a fixed voltage terminal, and which is connected to a time constant capacitor;
a control unit which compares the voltage at the control terminal with a predetermined threshold voltage, and which switches the function of the semiconductor device according to the comparison results; and
a charge/discharge circuit which charges or discharges the time constant capacitor connected to the control terminal,
wherein the voltage at the control terminal, which changes according to the charging operation or discharging operation performed by the charge/discharge circuit, is used as a time constant voltage.

2. A semiconductor device according to claim 1, wherein the control unit includes:
a determination comparator which compares the voltage at the control terminal with the threshold voltage; and
a latch circuit which latches the output of the determination comparator at a timing at which a trigger signal is generated when the semiconductor device is started up,
and wherein the function of the semiconductor device is switched according to the output of the latch circuit.

3. A semiconductor device according to claim 1, wherein the charge/discharge circuit includes:
a first time constant circuit which draws a sink current from the control terminal, and which compares the voltage at the control terminal with a first threshold voltage; and
a second time constant circuit which supplies a source current to the control terminal, and which compares the voltage at the control terminal with a second threshold voltage,
and wherein one of the first time constant circuit or the second time constant circuit is selected according to the comparison results made by the control unit.

4. A semiconductor device according to claim 1, further including a voltage source which generates a predetermined voltage; and
a voltage output terminal via which the voltage thus generated is output externally,
wherein the other terminal of the external resistor is connected to one of the voltage output terminal or the ground terminal.

5. A semiconductor device according to claim 4, wherein the time constant capacitor is connected between the control terminal and the voltage output terminal.

6. A semiconductor device according to claim 1, which is a driving circuit for a fluorescent lamp,
and which further includes a malfunction detection unit which detects whether or not a circuit malfunction continuously occurs during a predetermined malfunction detection period,
and wherein the voltage at the control terminal, which changes according to the charging operation or the discharging operation performed by the charge/discharge circuit, is used for timing the malfunction detection period.
